(19) United States
(12) Patent Application Publication
(10) Pub. No.: US 2026/0047143 A1
(43) Pub. Date: Feb. 12, 2026

(54) SEMICONDUCTOR DEVICE AND MANUFACTURING METHOD THEREOF

(71) Applicant: TAIWAN SEMICONDUCTOR MANUFACTURING COMPANY LTD., HSINCHU (TW)

(72) Inventors: YU-CHIEN CHIU, HSINCHU (TW); CHIEN-HAO HUANG, HSINCHU CITY (TW); YA-YUN CHENG, TAICHUNG CITY (TW); WEN-LING LU, TAOYUAN CITY (TW); CHUNG-WEI WU, HSIN-CHU COUNTY (TW); ZHIQIANG WU, HSINCHU COUNTY (TW)

(21) Appl. No.: 18/796,342

(22) Filed: Aug. 7, 2024

(51) Int. Cl. H01L 29/786; H01L 29/417; H01L 29/49; H01L 29/66; H10B 12/00

(52) U.S. Cl. CPC H10D 30/6755; H10B 12/488; H10D 30/031; H10D 30/6729; H10D 30/6739

(57) ABSTRACT

The present disclosure provides a semiconductor device and a manufacturing method thereof. The semiconductor device includes a gate dielectric layer, a gate electrode, and a barrier layer. The gate electrode surrounds the gate dielectric layer. The barrier layer is disposed between the gate dielectric layer and the gate electrode. The gate electrode is in contact with the barrier layer and the gate dielectric layer.

### BACKGROUND

Electronic equipment involving semiconductor devices is essential for many modern applications. Technological advances in materials and design have produced generations of semiconductor devices, each generation featuring smaller and more complex circuits than the previous generation. The semiconductor integrated circuit (IC) industry has produced a wide variety of digital devices to tackle challenges across various domains. Certain digital devices, such as memory devices, are configured for the storage of data. One promising option for such memory devices involves transistors with oxide semiconductor material known for its inherently high mobility.

### BRIEF DESCRIPTION OF THE DRAWINGS

Aspects of the present disclosure are best understood from the following detailed description when read with the accompanying figures. It is emphasized that, in accordance with standard practice in the industry, various features are not drawn to scale. In fact, the dimensions of the various features may be arbitrarily increased or reduced for clarity of discussion.

FIG. 1A is a cross-sectional view illustrating a semiconductor device in accordance with some embodiments of the present disclosure.

FIG. 1B is a schematic view illustrating a semiconductor device in accordance with some embodiments of the present disclosure.

FIG. 1C is a schematic diagram illustrating a memory array according to aspects of the present disclosure in one or more embodiments.

FIG. 2 is a cross-sectional view illustrating a semiconductor device in accordance with some embodiments of the present disclosure.

FIG. 3 is a cross-sectional view illustrating a semiconductor device in accordance with some embodiments of the present disclosure.

FIG. 4A is a cross-sectional view illustrating a semiconductor device in accordance with some embodiments of the present disclosure.

FIG. 4B is a schematic view illustrating a semiconductor device in accordance with some embodiments of the present disclosure.

FIG. 5A is a cross-sectional view illustrating a semiconductor device in accordance with some embodiments of the present disclosure.

FIG. 5B is a schematic view illustrating a semiconductor device in accordance with some embodiments of the present disclosure.

FIGS. 6A, 7A, 8A, 9A, 10A, 11A, 12A, 13A, 14A, 15A, 16A, 17A, and 18A are cross-sectional views of manufacturing a semiconductor device in accordance with some embodiments of the present disclosure.

FIGS. 6B, 7B, 8B, 9B, 10B, 11B, 12B, 13B, 14B, 15B, 16B, 17B, and 18B are schematic views of manufacturing a semiconductor device in accordance with some embodiments of the present disclosure.

FIG. 19 is a flow diagram of a method of manufacturing a semiconductor device in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Embodiments, or examples, illustrated in the drawings are disclosed as follows using specific language. It will nevertheless be understood that the embodiments and examples are not intended to be limiting. Any alterations or modifications in the disclosed embodiments, and any further applications of the principles disclosed in this document are contemplated as would normally occur to one of ordinary skill in the pertinent art.

Further, it is understood that several processing steps and/or features of a device may be only briefly described. Also, additional processing steps and/or features can be added, and certain of the following processing steps and/or features can be removed or changed while still implementing the claims. Thus, it is understood that the following descriptions represent examples only, and are not intended to suggest that one or more steps or features are required.

In addition, the present disclosure may repeat reference numerals and/or letters in the various examples. This repetition is for the purpose of simplicity and clarity and does not in itself dictate a relationship between the various embodiments and/or configurations discussed.

The present disclosure relates to a semiconductor memory device and a method of manufacturing a semiconductor memory device. The semiconductor memory device includes an omega-shaped transistor, including a gate electrode, an oxide semiconductor layer, a word line via, and a barrier layer. The barrier layer is disposed between the word line via and the oxide semiconductor layer. The barrier layer can reduce or eliminate the diffusion of hydrogens during the formation of the word line via. Thus, the number of hydrogen atoms/ions diffusing into the oxide semiconductor layer can be reduced. The omega-shaped transistor further includes a drain electrode. The barrier layer is disposed over and substantially vertically overlapped with the drain electrode. The barrier layer can increase the effective capacitance between the drain electrode and the gate electrode, and thus the charge sharing and operation speed of the semiconductor memory device can be improved. The location of the barrier layer is designed to be distant from the channel region of the oxide semiconductor layer, and thus the characteristics of the omega-shaped transistor can be retained.

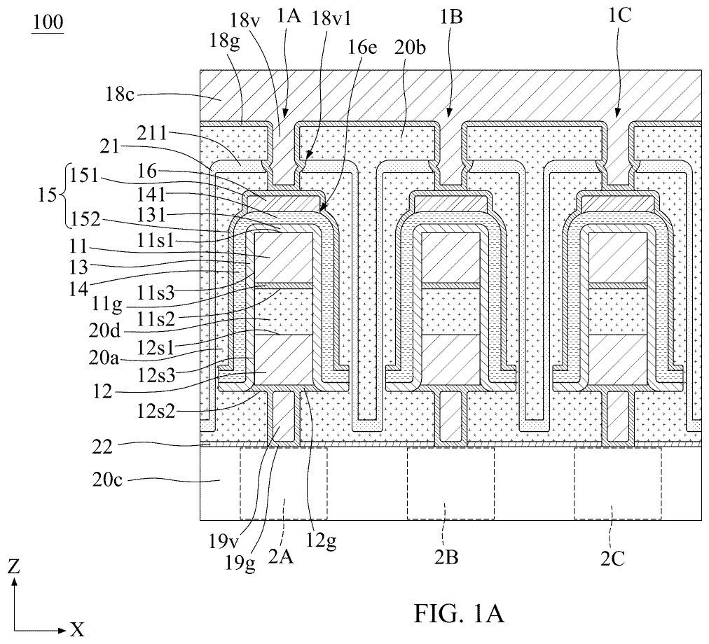

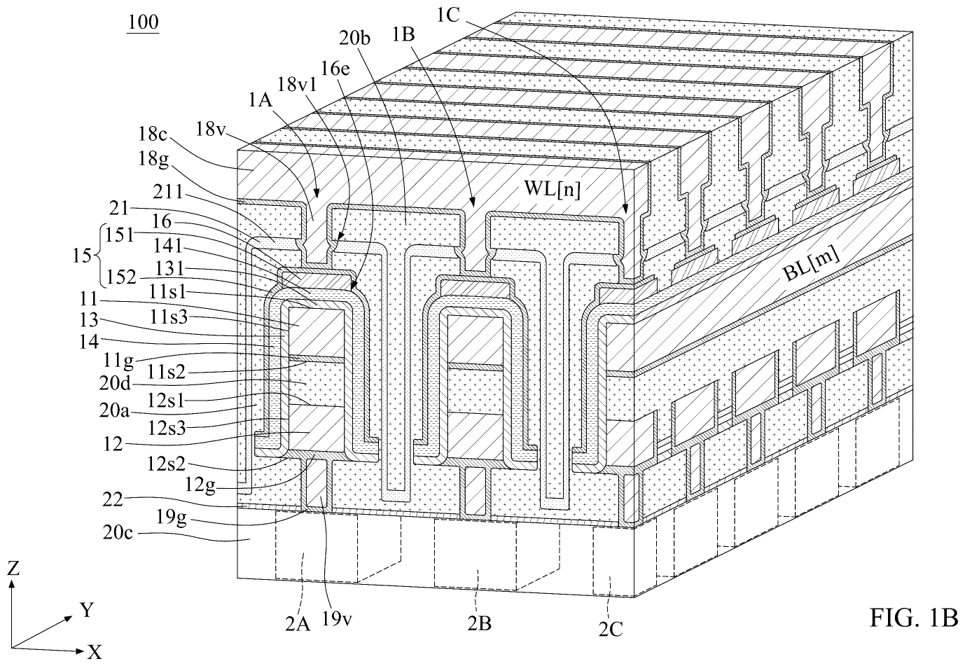

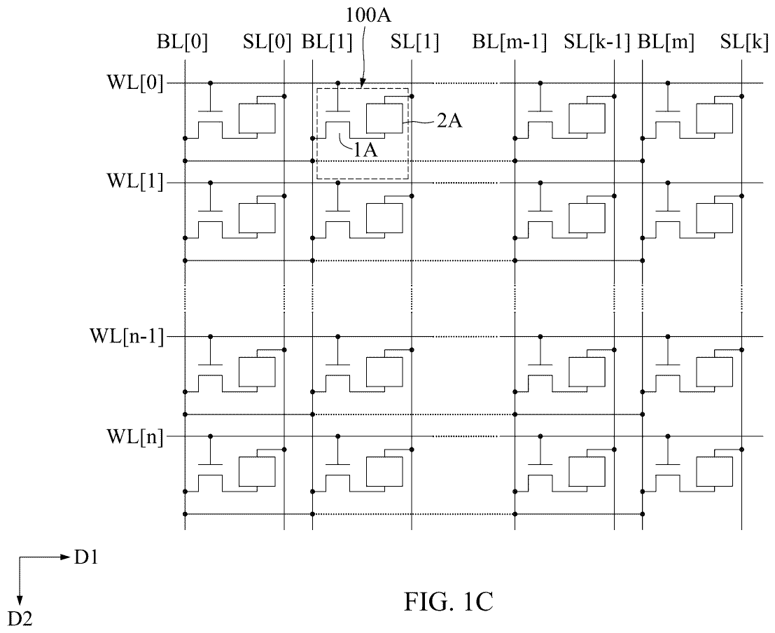

FIG. 1A is a cross-sectional view illustrating a semiconductor device 100 in accordance with some embodiments of the present disclosure. FIG. 1B is a schematic view illustrating the semiconductor device 100 in accordance with some embodiments of the present disclosure.

The semiconductor device 100 may include transistors 1A, 1B, and 1C and memory elements 2A, 2B, and 2C. The transistors 1A, 1B, and 1C respectively correspond to the memory elements 2A, 2B, and 2C. The transistors 1A, 1B, and 1C respectively connect to the memory elements 2A, 2B, and 2C. The semiconductor device 100 may be a semiconductor memory device. The semiconductor device 100 may include a plurality of memory cells, each of which includes one transistor and the corresponding memory element. The transistors 1A, 1B, and 1C are switches. When the transistors 1A, 1B, and 1C turn on in response to the control voltage from the word lines of the semiconductor device 100, the data stored in the corresponding memory element may be accessed or the corresponding memory element may be written. When the transistors 1A, 1B, and 1C turn off, the memory elements are disconnected from the bit lines of the semiconductor device 100.

The semiconductor device 100 may include DRAM, MRAM, RRAM, PCRAM, and ferroelectric tunnel junction (FTJ) memory. The transistors 1A, 1B, and 1C may serve as selectors for the memory elements 2A, 2B, and 2C. The memory elements 2A, 2B, and 2C may include DRAM elements (e.g., capacitors), MRAM elements (e.g., a magnetic tunneling junction (MTJ) element), RRAM elements, PCRAM elements, FTJ elements, or capacitors.

The transistors 1A, 1B, and 1C may each include a thin film transistor. The transistors 1A, 1B, and 1C may each include an oxide semiconductor thin film transistor. The transistors 1A, 1B, and 1C may each include a three-dimensional (3D) oxide semiconductor thin film transistor. Owing to the profile of the gate electrode, the transistors 1A, 1B, and 1C may be called thin film omega transistors.

Each of the transistors 1A, 1B, and 1C includes a gate electrode, a drain electrode, and a source electrode. In the present disclosure, the terms “gate electrode” and “gate” are interchangeable; the terms “drain electrode” and “drain” are interchangeable; and the terms “source electrode” and “source” are interchangeable.

The semiconductor device 100 includes a drain electrode 11, a source electrode 12, an oxide semiconductor layer 13, a gate dielectric layer 14, a gate electrode 15, a barrier layer 16, a conductive via 18v, a conductive trace 18c, a conductive via 19v, a plurality of insulating layers 20a, 20b, 20c, and 20d, a protection layer 21, and a passivation layer 22.

The transistor 1A includes the drain electrode 11, the source electrode 12, the oxide semiconductor layer 13, the gate dielectric layer 14, the gate electrode 15, and the barrier layer 16. The transistors 1B and 1C may each include structures/components identical to those of the transistor 1A.

The drain electrode 11 is disposed over the source electrode 12. The drain electrode 11 is surrounded by the oxide semiconductor layer 13, the gate dielectric layer 14, and/or the gate electrode 15 in the cross-sectional view in FIG. 1A. The drain electrodes 11 of each of the transistors 1A, 1B, and 1C arranged along the X direction may be separated from each other. Furthermore, in the schematic view of FIG. 1B, the drain electrodes 11 of each of the transistors 1A, 1B, and 1C may be shared by other transistors arranged along the Y direction. In FIG. 1B, the drain electrode 11 is indicated as a bit line BL[m] that is shared by the transistors arranged along the Y direction.

The drain electrode 11 has a top surface 11s1 facing the barrier layer 16, a bottom surface 11s2 facing the source electrode 12, and a lateral surface 11s3 connected between the top surface 11s1 and the bottom surface 11s2. The top surface 11s1 and the lateral surface 11s3 may be in contact with the oxide semiconductor layer 13. The drain electrode 11 may include a seed layer (or a drain seed layer) 11g disposed at the bottom surface 11s2 of the drain electrode 11.

In some embodiments, the material of the drain electrode 11 may include tungsten (W), molybdenum (Mo), ruthenium (Ru), tantalum nitride (TaN), titanium nitride (TiN), cobalt (Co), copper (Cu), aluminum (Al), indium tin oxide (ITO) or alloys thereof. In some embodiments, the material of the drain electrode 11 may include silicon, germanium, or the like.

In some embodiments, the material of the drain seed layer 11g may include tantalum nitride (TaN), titanium nitride (TiN), copper (Cu), or the like.

The source electrode 12 is disposed below the drain electrode 11. The source electrode 12 is surrounded by the oxide semiconductor layer 13, the gate dielectric layer 14, and/or the gate electrode 15 in the cross-sectional view in FIG. 1A. The source electrodes 12 of each of the transistors 1A, 1B, and 1C arranged along the X direction may be separated from each other. Furthermore, in the schematic view of FIG. 1B, the source electrodes 12 of each of the transistors arranged along the Y direction may be separated from each other. The source electrodes 12 of each of the transistors 1A, 1B, and 1C are connected to the corresponding ones of the memory elements 2A, 2B, and 2C through the conductive via 19v.

The conductive via 19v is disposed between the omega shaped transistor 1A and the memory element 2A. The conductive via 19v may include a seed layer 19g disposed along the bottom and sidewall of the conductive via 19v. The conductive via 19v may extend through the passivation layer 22 to connect the memory element 2A, 2B, or 2C. The passivation layer 22 disposed over the insulating layer 20c may isolate the memory elements 2A, 2B, and 2C from the circuit layer (or trace). The memory elements 2A, 2B, and 2C may be surrounded by the insulating layer 20c. In some embodiments, the material of the passivation layer 22 may include aluminum oxide (AlO) or the like.

The source electrode 12 has a top surface 12s1 in contact with the insulating layer 20d, a bottom surface 12s2 facing the memory element 2A, and a lateral surface 12s3 connected between the top surface 12s1 and the bottom surface 12s2. The lateral surface 12s3 may be in contact with the oxide semiconductor layer 13. The source electrode 12 may include a seed layer (or a source seed layer) 12g disposed at the bottom surface 12s2 of the source electrode 12.

In some embodiments, the material of the source electrode 12 may include tungsten (W), molybdenum (Mo), ruthenium (Ru), tantalum nitride (TaN), titanium nitride (TiN), cobalt (Co), copper (Cu), aluminum (Al), indium tin oxide (ITO) or alloys thereof. In some embodiments, the material of the source electrode 12 may include silicon, germanium, or the like. In some embodiments, the material of the source seed layer 12g may include tantalum nitride (TaN), titanium nitride (TiN), copper (Cu), or the like.

In some embodiments, the material of the conductive via 19v may include tungsten (W), tantalum nitride (TaN), titanium nitride (TiN), cobalt (Co), copper (Cu), aluminum (Al), or the like. In some embodiments, the material of the seed layer 19g may include tantalum nitride (TaN), titanium nitride (TiN), copper (Cu), or the like.

The thickness of the insulating layer 20d disposed between the drain electrode 11 and the source electrode 12 may be associated with a channel length of the transistor 1A. As the thickness increases, the channel length of the transistor 1A is longer.

In some embodiments, the insulating layers 20a, 20b, 20c, and 20d may be formed of low-κ dielectric material. In some embodiments, the insulating layers 20a, 20b, 20c, and 20d include materials such as spin-on dielectric (SOD), spin-on glass, spin-on polymers, silicon carbon material, un-doped silicate glass, or doped silicon oxide such as phosphor-silicate glass (PSG), borophosphosilicate glass (BPSG), fluorinated silicate glass (FSG), compounds thereof, composites thereof, combinations thereof, and/or other suitable dielectric materials. In some embodiments, the insulating layers 20a, 20b, 20c, and 20d may include silicon oxide (SiO), but the disclosure is not limited thereto.

The oxide semiconductor layer 13 is disposed along the top surface 11s1 and the lateral surface 11s3 of the drain electrode 11, a lateral surface of the insulating layer 20d, and the lateral surface 12s3 of the source electrode 12. The oxide semiconductor layer 13 may have an omega shape. The oxide semiconductor layer 13 may have a portion at substantially the same elevation as the bottom surface 12s2 of the source electrode 12.

In some embodiments, a channel region may be formed in the oxide semiconductor layers 13 in response to the voltage applied between the gate electrode 15 and the source electrode 12.

The oxide semiconductor layers 13 of each of the transistors 1A, 1B, and 1C arranged along the X direction may be separated from each other. Furthermore, in the schematic view of FIG. 1B, the oxide semiconductor layers 13 of each of the transistors 1A, 1B, and 1C may be shared by other transistors arranged along the Y direction.

In some embodiments, the oxide semiconductor layer 13 may include an oxide semiconductor material, such as indium zinc oxide (IZO), indium-gallium-zinc oxide (IGZO), zinc oxide (ZnO), indium oxide (InO), stannous oxide (SnO), copper oxide (CuO), nickel oxide (NiO), copper aluminum oxide, copper gallium oxide (CGO), copper indium oxide, strontium copper oxide (SCO), or the like, but is not limited to the above-mentioned materials.

The gate dielectric layer 14 is conformally disposed on the oxide semiconductor layer 13. The gate dielectric layer 14 may have an omega shape. The oxide semiconductor layer 13 may be disposed between the gate dielectric layer 14 and the drain electrode 11. The oxide semiconductor layer 13 may be disposed between the gate dielectric layer 14 and the source electrode 12.

In some embodiments, the gate dielectric layer 14 includes a high-κ dielectric material having a high dielectric constant. The high-κ dielectric material may include hafnium dioxide (HfO₂), zirconium dioxide (ZrO₂), aluminum oxide (Al₂O₃), lanthanum oxide (La₂O₃), titanium oxide (TiO₂), yttrium oxide (Y₂O₃), strontium titanate (SrTiO₃), hafnium oxynitride (HfOₓN_{y}), hafnium silicate, zirconium silicate, other suitable metal-oxides, metal silicates, or combinations thereof. The gate dielectric layer 14 may include silicon dioxide, silicon oxynitride.

The gate electrode 15 is disposed over the gate dielectric layer 14 and the barrier layer 16. The gate electrode 15 may be in contact with the barrier layer 16 and the gate dielectric layer 14. The gate electrode 15 surrounds the gate dielectric layer 14 and/or the oxide semiconductor layer 13. The gate electrode 15 may have an omega shape with a protrusion on the top thereof. The existence of the protrusion is a result of inserting the barrier layer 16 between the gate electrode 15 and the gate dielectric layer 14. In some embodiments, the gate electrode 15 may have a step structure. The step structure of the gate electrode 15 may be disposed over the drain electrode 11.

The step structure of the gate electrode 15 includes a first portion 151 and a second portion 152 connected to the first portion 151. The first portion 151 is separated from the gate dielectric layer 14, and the second portion 152 is in contact with the gate dielectric layer 14. The first portion 151th vertically overlaps the top surface 11s1 of the drain electrode 11 (i.e., overlapping the top surface 11s1 along the Z direction). The first portion 151 is conformally disposed on the barrier layer 16. The first portion 151 surrounds the barrier layer 16. The second portion 152 is conformally disposed on the gate dielectric layer 14. The first portion 151 and the second portion 152 may be formed during the same process step (e.g., deposition process). The deposition process includes chemical vapor deposition (CVD), physical vapor deposition (PVD), atomic layer deposition (ALD), other suitable methods, and/or combinations thereof.

In some embodiments, the material of the gate electrode 15 may include tungsten (W), tantalum nitride (TaN), titanium nitride (TiN), aluminum (Al), or alloys thereof. In some embodiments, the material of the gate electrode 15 may include silicon, germanium, or the like.

The barrier layer 16 is disposed between the gate electrode 15 and a top portion 141 of the gate dielectric layer 14. The top portion 141 is disposed below the barrier layer 16. The oxide semiconductor layer 13 includes a top portion 131 disposed below the barrier layer 16. The top portion 141 is stacked over the top portion 131.

The gate dielectric layer 14 and the gate electrode 15 meet at an edge 16e of the barrier layer 16. In some embodiments, there are three different materials which meet at the edge 16e of the barrier layer 16. In some embodiments, a first dielectric constant of the barrier layer 16 is smaller than a second dielectric constant of the gate dielectric layer 14. The barrier layer 16 with a relatively small dielectric constant can prevent the invasion/diffusion of hydrogen more effectively than the gate dielectric layer 14. In the present disclosure, the barrier layer 16 may be described as a “hydrogen stopping layer.”In some embodiments, the barrier layer 16 may include AlO, InO, HfO, other suitable metal-oxides, or combinations thereof. The barrier layer 16 may include SiN, SiCO, SiON, SiCON or the like. The barrier layer 16 may be formed by chemical vapor deposition (CVD), physical vapor deposition (PVD), atomic layer deposition (ALD), other suitable methods, and/or combinations thereof.

The conductive via (or the word line via) 18v is disposed over and connected to the gate electrode 15. The conductive trace (or the word line trace) 18c is disposed over and connected to the word line via 18v of each of the transistors 1A, 1B, and 1C. The conductive trace (or the word line trace) 18c is indicated as word line WL[n] as shown in FIG. 1B. The word line via 18v and the word line trace 18c may include a seed layer 18g. The seed layer 18g may be formed to facilitate the deposition of the word line via 18v and the word line trace 18c. The seed layer 18g is disposed along the bottom and sidewall of the word line via 18v and along the bottom of the word line trace 18c.

The word line via 18v and the word line trace 18c may be formed in the same process (e.g., the deposition process). The deposition process includes chemical vapor deposition (CVD), physical vapor deposition (PVD), atomic layer deposition (ALD), other suitable methods, and/or combinations thereof.

In some embodiments, the material of the word line via 18v and the word line trace 18c may include tungsten (W), tantalum nitride (TaN), titanium nitride (TiN), cobalt (Co), copper (Cu), aluminum (Al), or the like. In some embodiments, the material of the seed layer 18g may include tantalum nitride (TaN), titanium nitride (TiN), copper (Cu), or the like. In some embodiments, the material of the seed layer 18g and the gate electrode 15 may be different. In some embodiments, the material of the seed layer 18g and the gate electrode 15 may be the same.

The word line via 18v is disposed over the barrier layer 16. The word line via 18v vertically overlaps the barrier layer 16 (i.e., overlapping the barrier layer 16 in the Z direction). The width of the barrier layer 16 is larger than the width of the word line via 18v in the X direction. The barrier layer 16 is disposed between the oxide semiconductor layer 13 and the word line via 18v. The conductive via 18v is substantially aligned with the barrier layer 16 in the Z direction. The drain electrode 11 is substantially aligned with the conductive via 18v and the barrier layer 16 in the Z direction. The source electrode 12 is substantially aligned with the drain electrode 11, the conductive via 18v, and the barrier layer 16 in the Z direction. The thickness of the barrier layer 16 may be larger than a value such that the barrier layer 16 is able to stop the migration of hydrogen. The thickness of the barrier layer 16 may be in a range from 3 nm to 100 nm. The barrier layer 16

[symbol]

In the deposition process of the word line via 18v and the word line trace 18c, a carrier (e.g., a wafer) that includes the intermediate (or semi-finished) structure of the semiconductor device 100 is loaded into a chamber (e.g., CVD chamber). Furthermore, in the deposition process of insulating layers (or passivation layers), the intermediate structure of the semiconductor device 100 is loaded into a chamber (e.g., CVD or ALD chamber). In some cases, the carrier gases (e.g., hydrogen with a considerable amount) of the chamber may invade/diffuse/migrate/permeate from the word line via 18v into a gate electrode and an inner gate dielectric layer and a channel region (e.g., in an oxide semiconductor layer). Hydrogen within the metal material (e.g., the word line via 18v) exhibits low migration energy, allowing it to traverse or diffuse through the metal material into the channel region. Furthermore, the thermal treatment processes (around 200˜300°) of the formation of the word line via 18v and the word line 18c may facilitate the migration of hydrogen into the active layer. The characteristics of the gate dielectric layer and the channel region can be adversely affected by the hydrogen impurity. For example, the doping concentration of the channel region may be changed by the hydrogen, resulting in an unwanted shift of the threshold voltage. In some cases, the channel region may be difficult to be turned off.

In the present disclosure, the semiconductor device 100 includes the barrier layer 16 disposed between the word line via 18v and the gate dielectric layer 14 /the oxide semiconductor layer 13. The barrier layer 16 is configured to reduce or stop the invasion/diffusion/migration/permeation of hydrogen into the gate dielectric layer 14 and the oxide semiconductor layer 13 during the deposition process of the word line via 18v and the word line trace 18c.

Furthermore, when a suitable voltage is applied between gate electrode 15 and the source electrode 12 of the transistor 1A, a conductive channel in the oxide semiconductor layer 13 is turned on to electrically connect the source electrode 12 to the drain electrode 11. The magnitude of the suitable voltage is determined by the threshold voltage of each of the transistors 1A, 1B, and 1C. With decreased or eliminated hydrogen diffusion into the oxide semiconductor layer 13, the threshold voltage can be improved.

The barrier layer 16 may increase the equivalent distance between the gate electrode 15 and the drain electrode 11. The equivalent gate-drain capacitance (e.g., C_{gd}) between the gate electrode 15 and the drain electrode 11 can be reduced. Owing to the decreased C_{gd}, the switching speed of the transistors 1A, 1B, and 1C can be improved. The charge sharing (or the charge sharing ratio) of the semiconductor device 100 can be enhanced. The operation speed of the semiconductor device 100 can be increased, while the RC delay time can be reduced.

The conductive channel of the oxide semiconductor layer 13 is mainly located between the drain electrode 11 and the source electrode 12. The barrier layer 16 is disposed on the top portion 141 of the gate dielectric layer 14 and the top portion 131 of the oxide semiconductor layer 13. The other portion (i.e., a lateral portion) of the gate dielectric layer 14 is still in contact with the second portion 152 of the gate electrode 15. The state (“on” or “off”) of the conductive channel is mainly controlled by the second portion 152 of the gate electrode 15 and the lateral portion of the gate dielectric layer 14. Therefore, the barrier layer 16 on the top portions 131 and 141 may have a minor influence on the characteristics of the transistor 1A.

The protection layer 21 is disposed over the insulating layer 20a. The insulating layer 20a surrounds each of the transistors 1A, 1B, and 1C. The insulating layer 20a may surround the gate electrode 15.

The second portion 152 of the gate electrode 15 may have an end adjacent to the protection layer 21 and have a round shape. The oxide semiconductor layer 13 may have an end adjacent to the protection layer 21 and have a round shape. The round shape of the end may be formed by an etching process.

The protection layer 21 surrounds each of the transistors 1A, 1B, and 1C. The protection layer 21 isolates the transistors 1A, 1B, and 1C from the word line trace 18c. The protection layer 21 isolates the transistors 1A, 1B, and 1C from each other.

The insulating layer 20b is disposed below the word line trace 18c. The insulating layer 20b may surround the word line via 18v. The insulating layer 20b is disposed over the protection layer 21.

The word line via 18v may extend through a top portion 211 of the protection layer 21. The word line via 18v may have a portion 18v1 with a diamond shape. The portion 18v1 is at the same elevation as the top portion 211 of the protection layer 21. The top portion 211 may have a sidewall with a shape complementary to the diamond shape of the portion 18v1. The section of the top portion 211 that is in contact with the portion 18v1 may have a round shape. During the etching process of the insulating layers 20a and 20b and the protection layer 21 prior to the deposition of the word line via 18v, a lateral etching phenomenon occurs at the protection layer 21. The diamond shape of the portion 18v1 reflects the lateral etching phenomenon. The width of the portion 18v1 may decrease from its center to its top and bottom sides. The portion 18v1 may vertically overlap the barrier layer 16 (or overlap the barrier layer 16 along the Z direction).

In some embodiments, the material of the protection layer 21 may include aluminum oxide (AlO) or the like. The protection layer 21 may be configured to reduce or stop the invasion/diffusion/migration/permeation of hydrogen into the gate dielectric layer 14 and the oxide semiconductor layer 13 during the deposition process of the word line via 18v and the word line trace 18c.

In some embodiments, the transistor 1A may serve as a selector for the memory element 2A. FIG. 1C is a schematic diagram illustrating a memory array 500 according to aspects of the present disclosure in one or more embodiments.

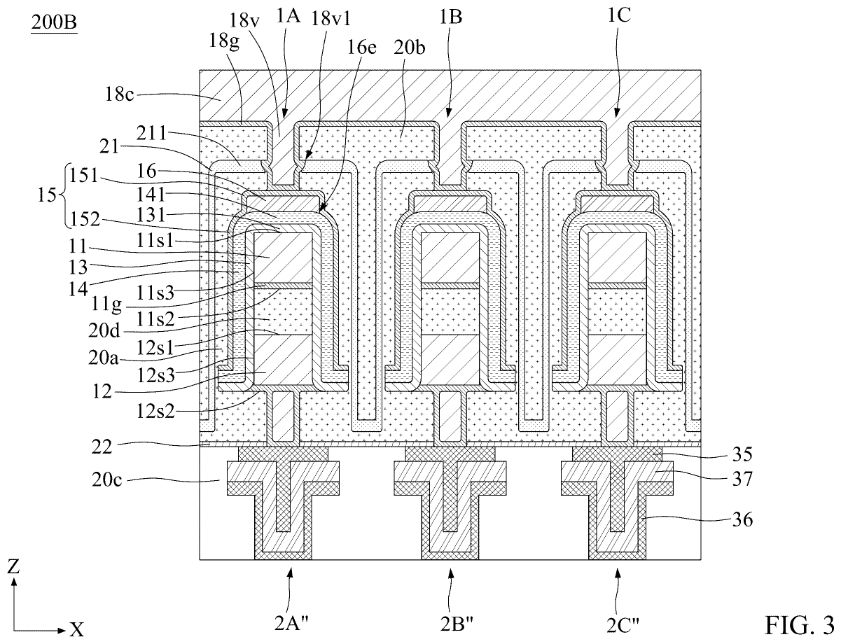

Referring to FIG. 3, the memory array 500 includes a plurality of memory elements and a plurality of transistors. In some embodiments, the transistors are configured to access the corresponding memory elements. The transistor 1A is included in the plurality of transistors and the memory element 2A is included in the plurality of memory elements. In some embodiments, the memory array 500 includes a plurality of memory units. A memory unit 100A thereof includes the transistor 1A and the memory element 2A. The plurality of memory units may each include similar or identical components to those of the memory unit 100A. In some embodiments, the memory unit 100A may be a DRAM unit, a RRAM unit, a MRAM unit, a PCRAM unit, a FTJ memory unit.

The memory array 500 further includes bit lines BL, word lines WL and supply lines SL. The bit lines BL are labeled BL[0] through BL[m] in a first direction D1, the word lines are labeled WL[0] through WL[n] in a second direction D2, and the supply lines SL are labeled SL[0] through SL[k] in the first direction D1. The second direction D2 is substantially perpendicular to the first direction D1. The bit line BL is electrically coupled to the drain electrodes of the corresponding transistor (e.g., the bit line BL[1] is electrically coupled to the drain electrode of the transistor 1A). In some embodiments, a single bit line BL is coupled to a number of transistors in the second direction D2.

The supply line SL is electrically coupled to the corresponding memory element (e.g., the supply line SL[1] is electrically coupled to the memory element 2A). In some embodiments, a single supply line SL is coupled to a number of memory elements in the second direction D2. A supply voltage (or a reference voltage or ground) may be applied to the memory element 2A through the supply line SL[1].

The word line WL is electrically coupled to the corresponding transistor (e.g., the word line WL is electrically coupled to the transistor 1A). In some embodiments, a single word line WL is coupled to a number of transistors in the first direction D1. In some embodiments, application of a suitable word line WL voltage to the gate electrode of the transistor 1A controls the state of the transistor 1A. When the transistor 1A turns on in response to the voltage from the word line WL[0], the data stored in the memory element 2A may be accessed or the memory element 2A may be written through the bit line BL[1]. When the transistor 1A turns off, the memory element 2A is disconnected from the bit line BL[1].

The gate electrode of the transistor 1A may be electrically connected to the word line WL, such as the word line WL[0]. The source electrode of the transistor 1A may be electrically connected to the memory element 2A. The drain electrode of the transistor 1A may be electrically connected to the bit line BL, such as the bit line BL[1].

The semiconductor device 100 may undergo further processes to form various features such as contacts/vias, interconnect metal layers, dielectric layers, passivation layers, etc. In some embodiments, prior to the formation of the semiconductor device 100, a FEOL circuit level may be formed. In some embodiments, the semiconductor device 100 may be embedded in the BEOL circuit level.

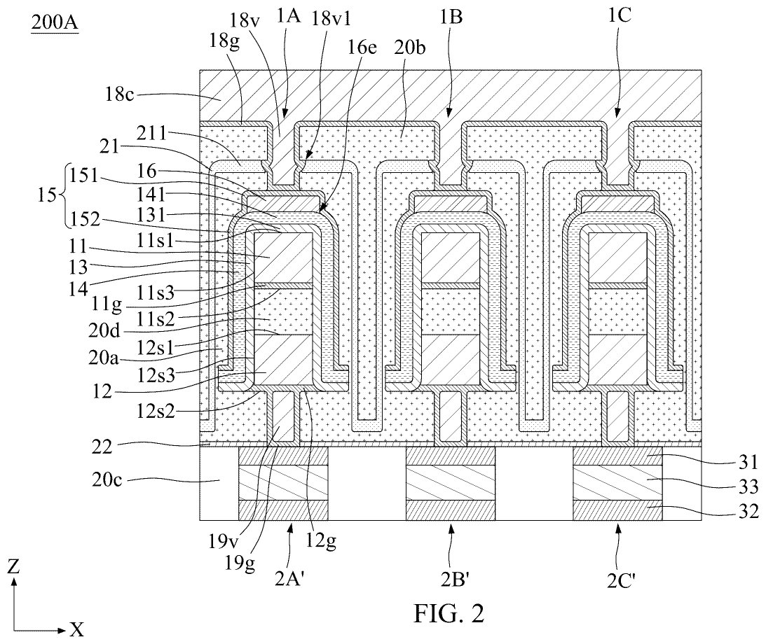

FIG. 2 is a cross-sectional view illustrating a semiconductor device 200A in accordance with some embodiments of the present disclosure. The structure of the semiconductor device 200A is similar to the structure of the semiconductor device 100. Therefore, some detailed descriptions may refer to corresponding preceding paragraphs and are not repeated hereinafter for conciseness, with differences therebetween as follows.

The semiconductor device 200A includes memory elements 2A′, 2B′, and 2C′, each of which includes a sandwiched structure including a first layer 31, a second layer 32, and an intermediate layer 33 sandwiched between the first layer 31 and the second layer 32. The first layer 31 may be connected to the source electrode 12 of each of the transistors 1A, 1B, and 1C. The first layer 34 may be connected to the conductive via 19v. The second layer 32 may be connected to the supply line SL as shown in FIG. 1C.

In some embodiments, the semiconductor device 200A may include DRAM. The sandwiched structure may be a capacitor for the data storage. The first layer 31 and the second layer 32 may be electrically conductive. The intermediate layer 33 may be electrically insulative. The number of charges stored in the capacitor represents the data, such as logic high (“1”) or logic low (“0”). The transistor 1A may be turned on to connect the memory element 2A′ to the bit line BL (or the drain electrode 11). The data of the capacitor may be accessed or written.

In some embodiments, the semiconductor device 200A may include RRAM. The first layer 31 and the second layer 32 may be electrically conductive. The intermediate layer 33 may be electrically insulative. The intermediate layer 33 may be metal oxide. The resistance of the intermediate layer 33 may have multiple states of electrical resistance, each of which represents the stored data, such as logic high (“1”) or logic low (“0”). The transistor 1A may be turned on to connect the memory element 2A′ to the bit line BL (or the drain electrode 11). The data (or the state) of the sandwiched structure may be accessed or written.

In some embodiments, the semiconductor device 200A may include MRAM. The first layer 31 and the second layer 32 may be ferromagnetic. The intermediate layer 33 may be a tunneling barrier layer. The intermediate layer 33 may be metal oxide. The memory element 2A′ can be switched between two states of electrical resistance, i.e., a first state with a low resistance (wherein magnetization directions of the first layer 31 and the second layer 32 are parallel) and a second state with a high resistance (wherein magnetization directions of the first layer 31 and the second layer 32 are antiparallel), to store data. The transistor 1A may be turned on to connect the memory element 2A′ to the bit line BL (or the drain electrode 11). The data (or the state) of the sandwiched structure may be accessed or written.

In some embodiments, the semiconductor device 200A may include PCRAM. The first layer 31 and the second layer 32 may be electrically conductive. The intermediate layer 33 may include chalcogenide glass. The phase of the chalcogenide glass may be switched between amorphous (high resistance) and crystalline (low resistance). The phase represents the data, such as logic high (“1”) or logic low (“0”). The transistor 1A may be turned on to connect the memory element 2A′ to the bit line BL (or the drain electrode 11). The data of the capacitor may be accessed or written.

FIG. 3 is a cross-sectional view illustrating a semiconductor device 200B in accordance with some embodiments of the present disclosure. The structure of the semiconductor device 200B is similar to the structure of the semiconductor device 100. Therefore, some detailed descriptions may refer to corresponding preceding paragraphs and are not repeated hereinafter for conciseness, with differences therebetween as follows.

The semiconductor device 200B includes memory elements 2A″, 2B″, and 2C″, each of which includes a 3D metal-insulator-metal (MIM) structure. The 3D MIM structure includes a first layer 35, a second layer 36, and a dielectric layer 37 disposed between the first layer 35 and the second layer 36. The first layer 35 may be connected to the source electrode 12 of each of the transistors 1A, 1B, and 1C. The first layer 35 may be connected to the conductive via 19v. The second layer 36 may be connected to the supply line SL as shown in FIG. 1C.

The first layer 35 may include a vertical portion extending along the X direction and a horizontal portion extending along the Z direction. The second layer 36 may include a vertical portion extending along the X direction and a horizontal portion extending along the Z direction. The vertical portion of the first layer 35 is disposed in a hole defined by the vertical portion of the second layer 36. The horizontal portion of the first layer 35 is disposed over the horizontal portion of the second layer 36.

The dielectric layer 37 may have a topography conforming to the second layer 36. In other words, the dielectric layer 37 may have a portion conformal to the vertical portion of the second layer 36 and a further portion conformal to the horizontal portion of the second layer 36.

The 3D MIM structure as shown in FIG. 3 may be a capacitor. The 3D MIM structure of FIG. 3 may have higher capacitance than the sandwich structure of FIG. 2.

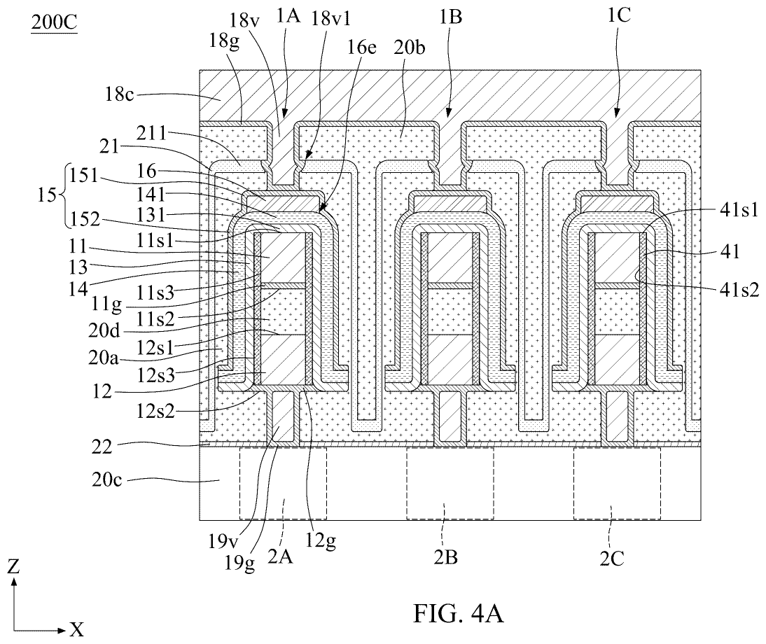

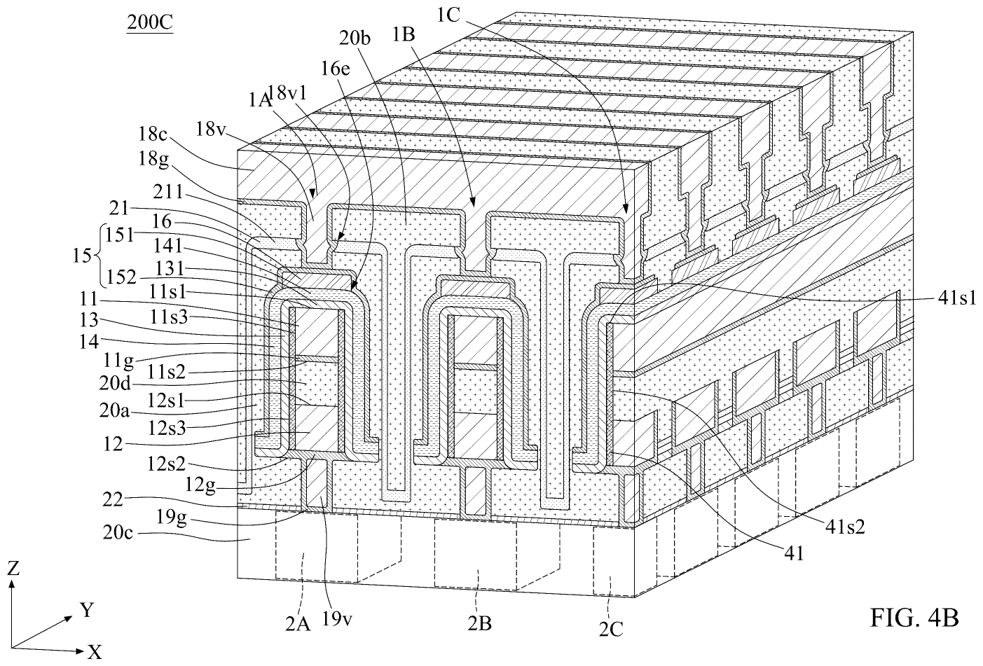

FIG. 4A is a cross-sectional view illustrating a semiconductor device 200C in accordance with some embodiments of the present disclosure. FIG. 4B is a schematic view illustrating the semiconductor device 200C in accordance with some embodiments of the present disclosure. The structure of the semiconductor device 200C is similar to the structure of the semiconductor device 100. Therefore, some detailed descriptions may refer to corresponding preceding paragraphs and are not repeated hereinafter for conciseness, with differences therebetween as follows.

The semiconductor device 200C includes a second oxide semiconductor layer 41 disposed between the oxide semiconductor layer 13 and the drain electrode 11. A first doping concentration of the second oxide semiconductor layer 41 is smaller than a second doping concentration of the oxide semiconductor layer 13. The first doping concentration of the second oxide semiconductor layer 41 may be around 10¹⁵˜10¹⁷ cm⁻³. The second doping concentration of the oxide semiconductor layer 13 may be around 10¹⁷˜10¹⁹ cm⁻³. The thickness of the oxide semiconductor layer 13 may be around 0.5˜100 nm. The thickness of the second oxide semiconductor layer 41 may be around 0.5˜100 nm. The thickness is equal to or greater than 0.5 nm to form a reliable film. The thickness is equal to or less than 100 nm to ensure the quality of the film formed by the ALD process. The second oxide semiconductor layer 41 has a short side 41s1 substantially coplanar with the top surface 11s1 of the drain electrode 11. The second oxide semiconductor layer 41 has a long side 41s2 in contact with the lateral surface 11s3 of the drain electrode 11 and the lateral surface 12s3 of the source electrode 12.

In some embodiments, the second oxide semiconductor layer 41 may include an oxide semiconductor material, such as indium zinc oxide (IZO), indium-gallium-zinc oxide (IGZO), zinc oxide (ZnO), indium oxide (InO), stannous oxide (SnO), copper oxide (CuO), nickel oxide (NiO), copper aluminum oxide, copper gallium oxide (CGO), copper indium oxide, strontium copper oxide (SCO), or the like, but is not limited to the above-mentioned materials. The dopant of the second oxide semiconductor layer 41 and the oxide semiconductor layer 13 may be the same, while the proportions of elements are different, e.g., the proportion of Indium of the oxide semiconductor layer 13 may be larger than that of the second oxide semiconductor layer 41.

The second oxide semiconductor layer 41 with lower doping concentration may increase the threshold voltage of the transistor 1A. The multiple oxide semiconductor layers 13 and 41 can reduce the charge traps formed at the interface between the gate dielectric layer 14 and the multiple oxide semiconductor layers 13 and 41. The second oxide semiconductor layer 41 can improve the negative bias temperature instability (NBTI) and/or the positive bias temperature instability (PBTI).

FIGS. 4A and 4B show two oxide semiconductor layers surrounded by the gate dielectric layer 14. However, embodiments of the disclosure are not limited thereto. Many variations and/or modifications can be made to embodiments of the disclosure. In some embodiments, the number of oxide semiconductor layers can be more than two.

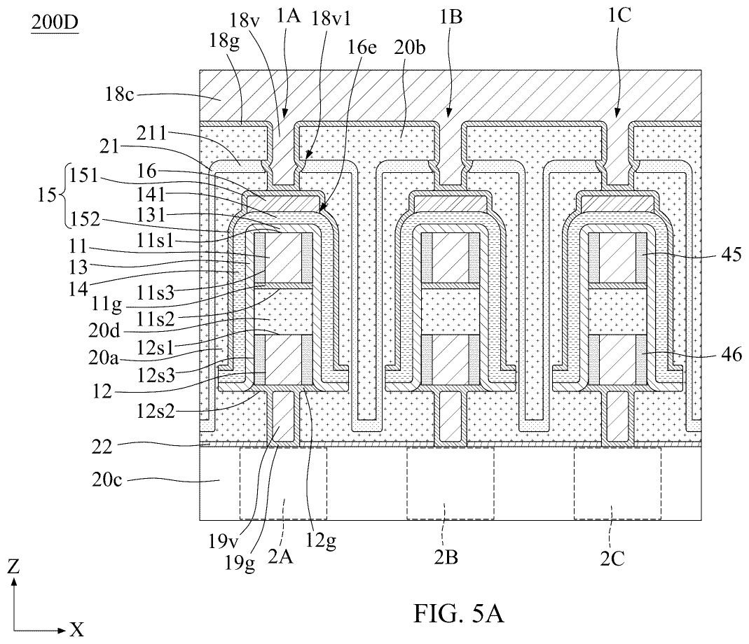

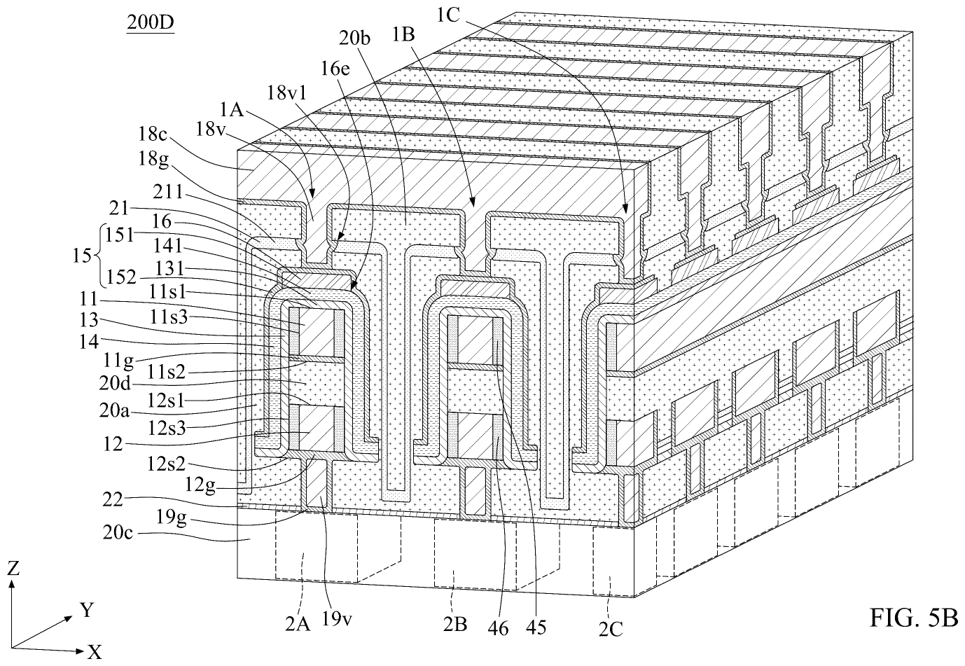

FIG. 5A is a cross-sectional view illustrating a semiconductor device 200D in accordance with some embodiments of the present disclosure. FIG. 5B is a schematic view illustrating the semiconductor device 200D in accordance with some embodiments of the present disclosure. The structure of the semiconductor device 200D is similar to the structure of the semiconductor device 100. Therefore, some detailed descriptions may refer to corresponding preceding paragraphs and are not repeated hereinafter for conciseness, with differences therebetween as follows.

The semiconductor device 200D includes a liner 45 disposed along the lateral surface 11s3 of the drain electrode 11, and a liner 46 disposed along the lateral surface 12s3 of the source electrode 12. A doping concentration of the liner 45 is between a doping concentration of the drain electrode 11 and a doping concentration of the oxide semiconductor layer 13. A doping concentration of the liner 46 is between a doping concentration of the source electrode 12 and a doping concentration of the oxide semiconductor layer 13. The liner 45 can reduce the contact resistance between the drain electrode 11 and the oxide semiconductor layer 13. The liner 46 can reduce the contact resistance between the source electrode 12 and the oxide semiconductor layer 13.

In some embodiments, the doping concentration of the liners 45 and 46 may be around 10²⁰˜10²¹ cm⁻³. In some embodiments, the doping concentration of the drain electrode 11 (or the source electrode 12) may be around 10²² cm⁻³. In some embodiments, the doping concentration of the oxide semiconductor layer 13 may be around 10¹⁸ cm⁻³.

In some embodiments, the liner 45 and the liner 46 may include an oxide semiconductor material, such as indium-gallium-zinc oxide (IGZO), zinc oxide (ZnO), indium oxide (InO), cerium oxide (CeO), indium tin oxide (ITO), titanium oxide (TiO), or the like, but are not limited to the above-mentioned materials.

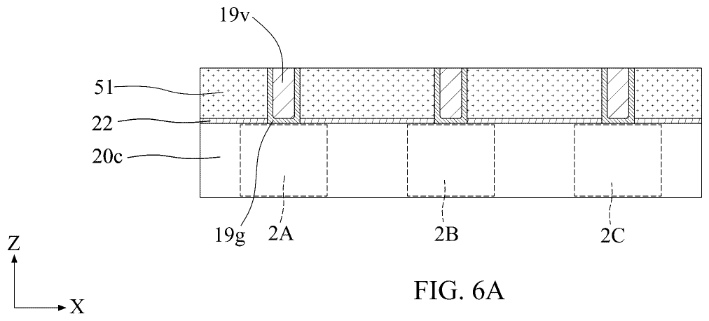

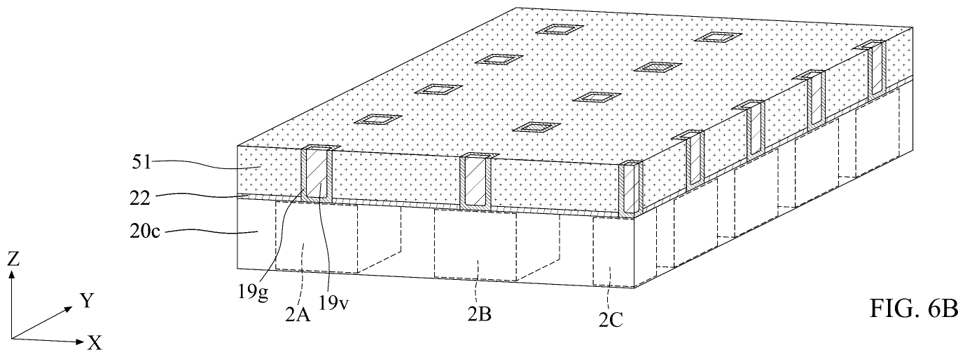

FIGS. 6A, 7A, 8A, 9A, 10A, 11A, 12A, 13A, 14A, 15A, 16A, 17A, and 18A are cross-sectional views of manufacturing a semiconductor device (e.g., the semiconductor device 100) in accordance with some embodiments of the present disclosure. FIGS. 6B, 7B, 8B, 9B, 10B, 11B, 12B, 13B, 14B, 15B, 16B, 17B, and 18B respectively correspond to FIGS. 6A, 7A, 8A, 9A, 10A, 11A, 12A, 13A, 14A, 15A, 16A, 17A, and 18A and are schematic views of manufacturing a semiconductor device (e.g., the semiconductor device 100) in accordance with some embodiments of the present disclosure.

In FIGS. 6A to 18A and 6B to 18B, similar reference numerals will be assigned to corresponding portions described above, avoiding redundant descriptions. In addition, portions for which no particular description is made have constructions similar to those of semiconductor device 100 described above, and provide the same advantages.

In FIGS. 6A and 6B, a plurality of memory elements (including the memory elements 2A, 2B, and 2C) may be formed in an insulating layer 20c. The memory elements may be spaced apart from each other. A passivation layer 22 may be formed over the insulating layer 20c. An insulating material 51 may be formed over the insulating layer 20c. A conductive via 19v may be formed in a hole defined by the insulating material 51 to connect each of the memory elements 2A, 2B, and 2C. A seed layer 19g may be formed along the bottom and sidewall of the conductive via 19v.

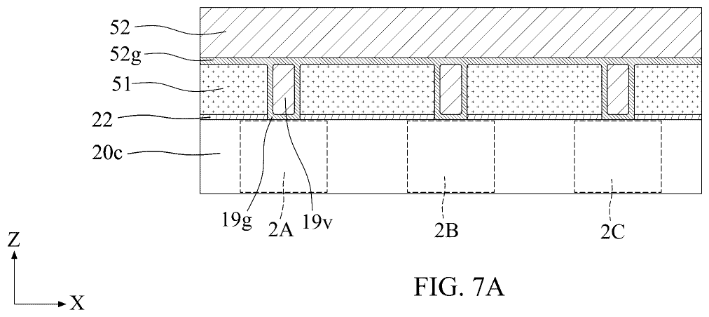

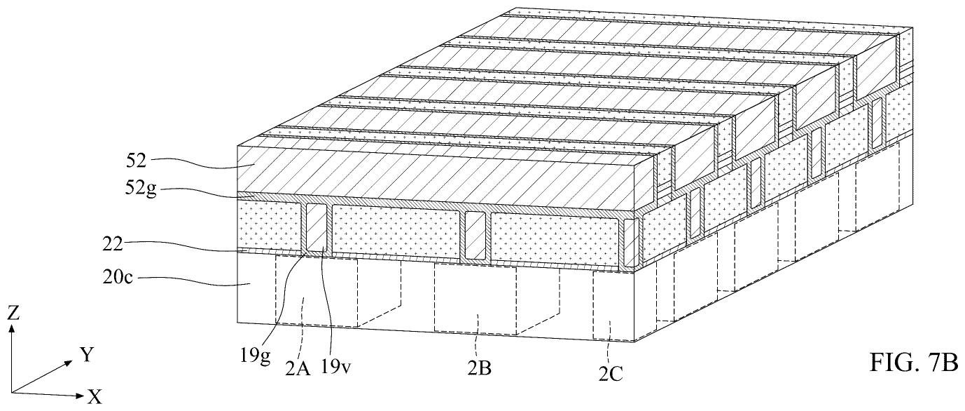

In FIGS. 7A and 7B, an insulating material 70 may be formed over the conductive via 19v and the insulating layer 20c. The insulating material 70 may be etched to have a trench directly above the conductive via 19v. A conductive material 52 and a seed material 52g are formed in the trench to connect the conductive via 19v.

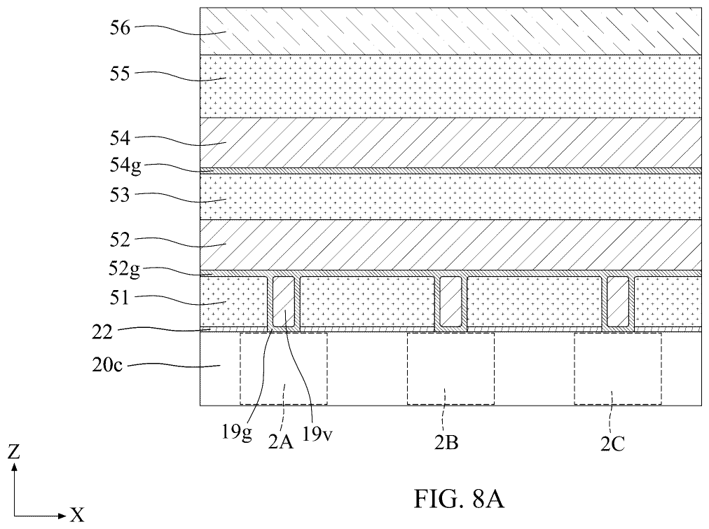

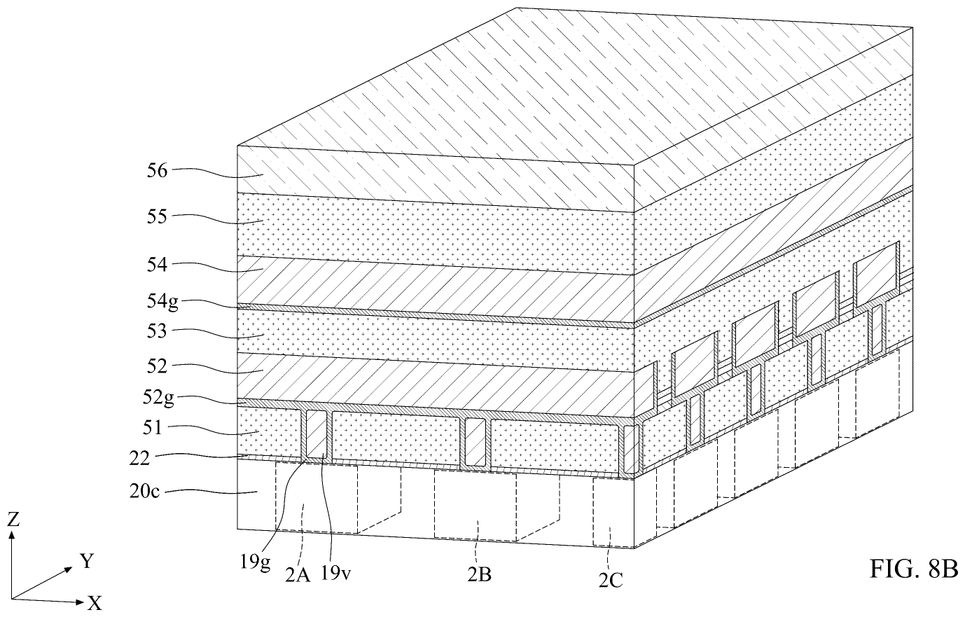

In FIGS. 8A and 8B, an insulating material 53, a conductive material 54, an insulating material 55, and a hard mask layer 56 may be formed in sequence over the conductive material 52 and the insulating material 70.

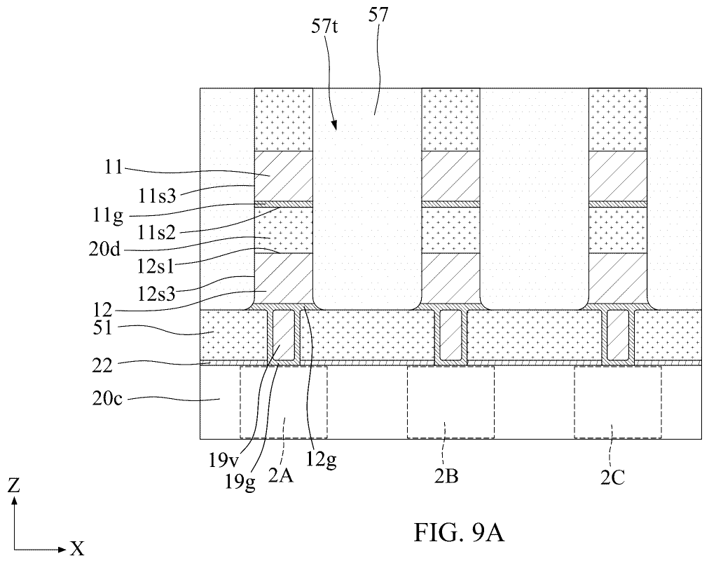

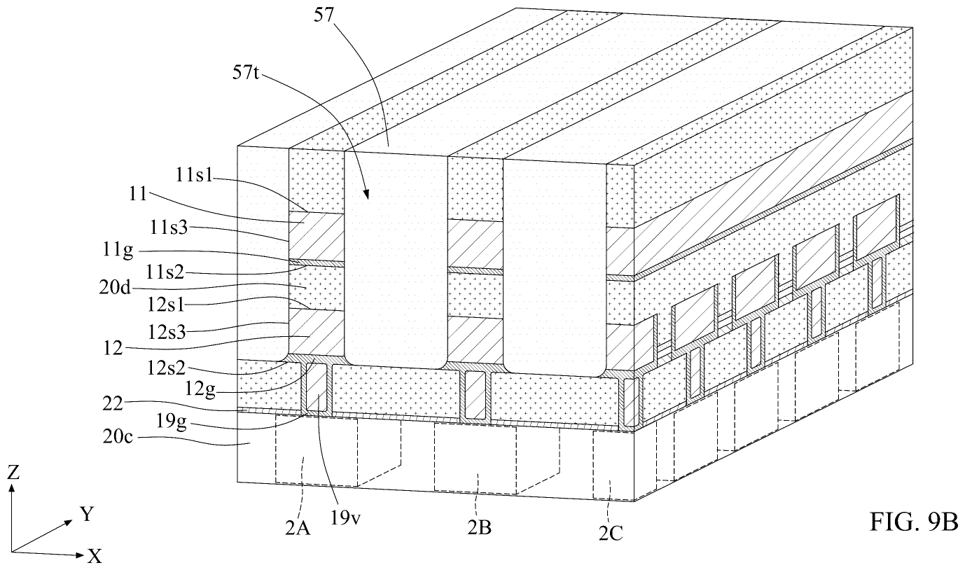

In FIGS. 9A and 9B, a drain electrode 11, a source electrode 12, and/or an insulating layer 20d are formed by etching the insulating material 53, the conductive material 54, the insulating material 55, conductive material 52, and the insulating material 70. During the etching process, a plurality of trenches 57t may be formed and a sacrificial layer 57 may then be disposed in the trenches.

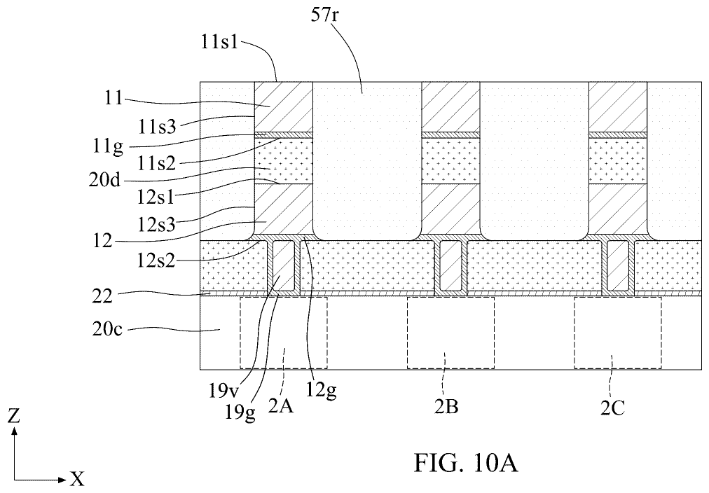

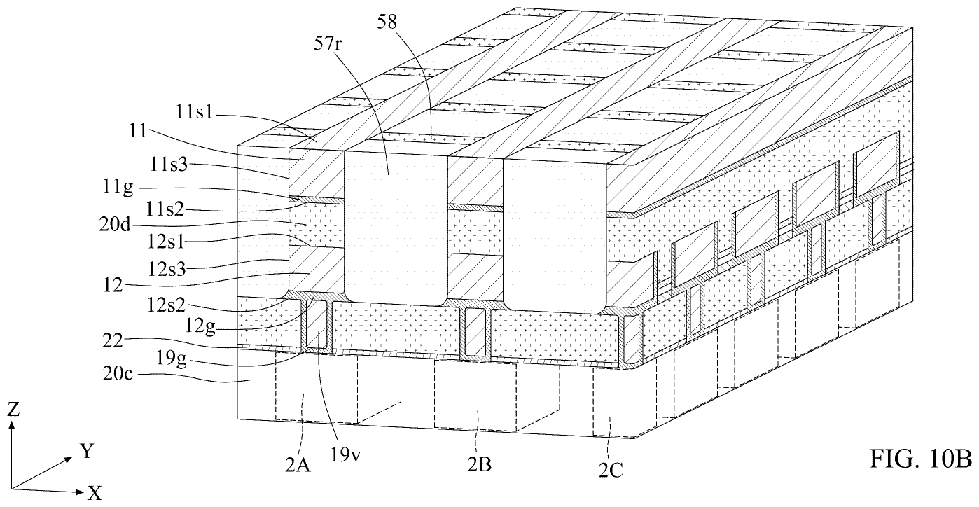

In FIGS. 10A and 10B, the sacrificial layer 57 is partitioned into a plurality of regions 57r. The regions 57r are separated from each other by an insulating layer 58.

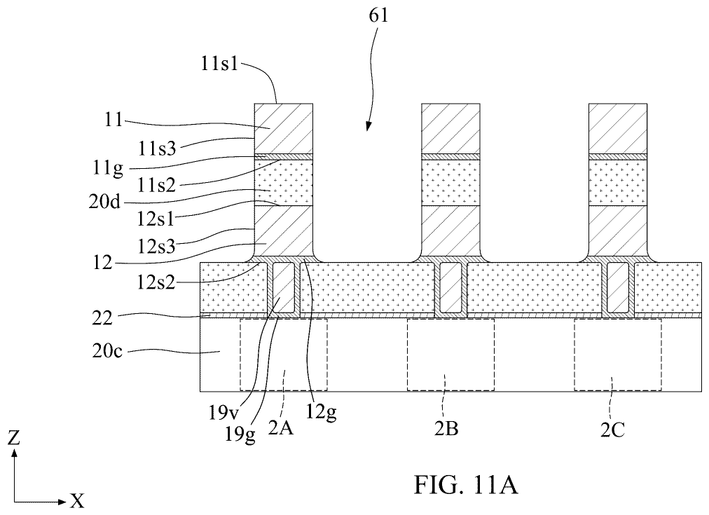

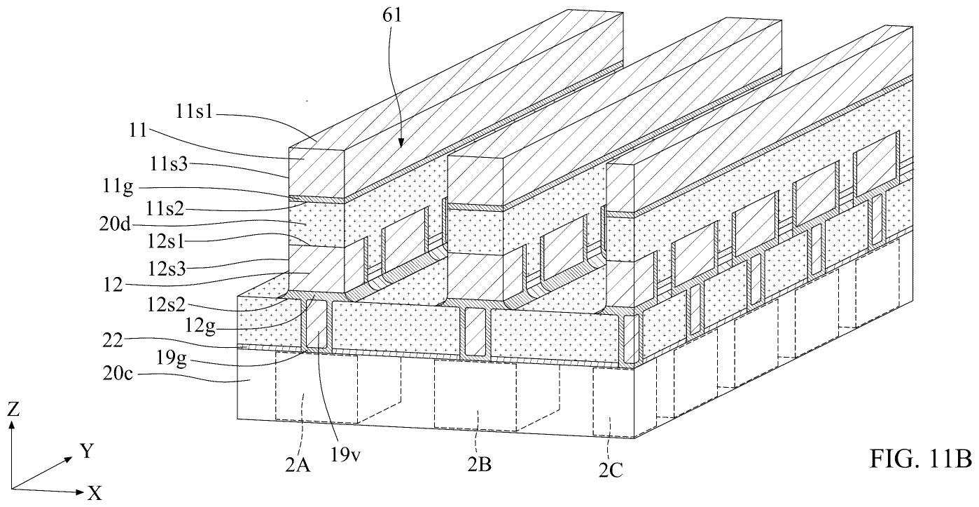

In FIGS. 11A and 11B, the regions 57r of the sacrificial layer 57 are removed to define a plurality of holes 61. The material of the sacrificial layer 57 may include silicon nitride.

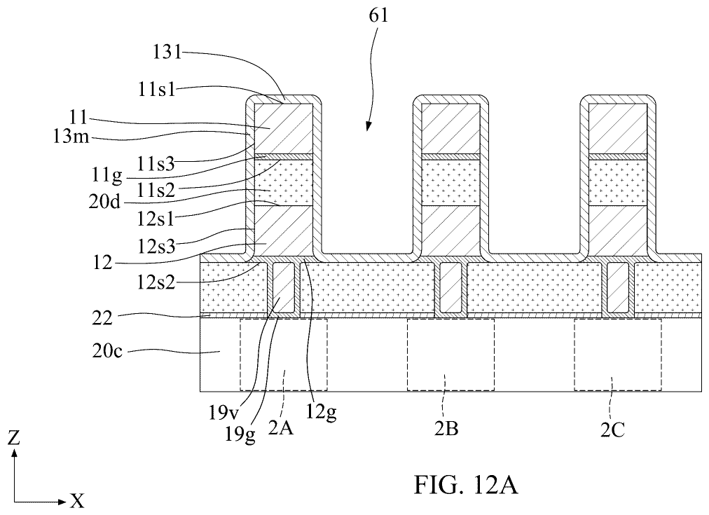

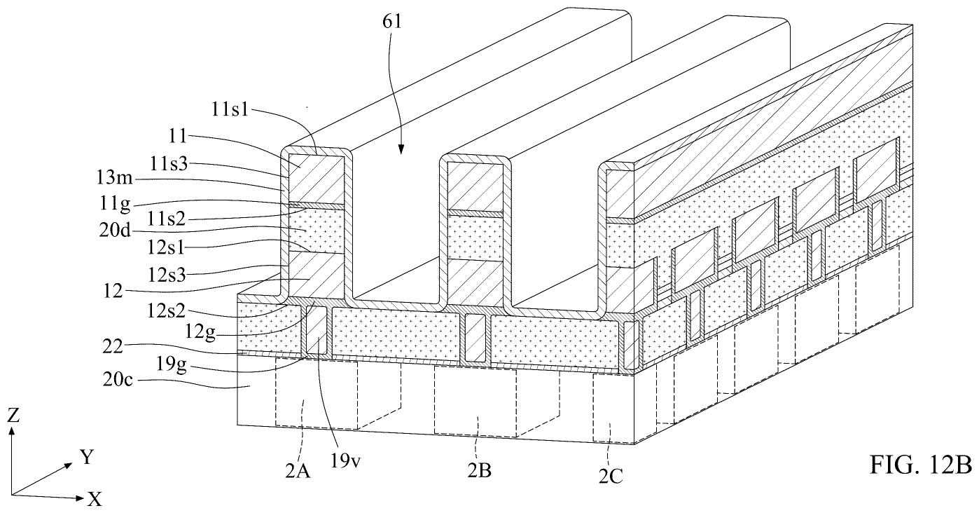

In FIGS. 12A and 12B, an oxide semiconductor layer material 13m is formed over the drain electrode 11, the insulating layer 20d, the source electrode 12, and the insulating material 51.

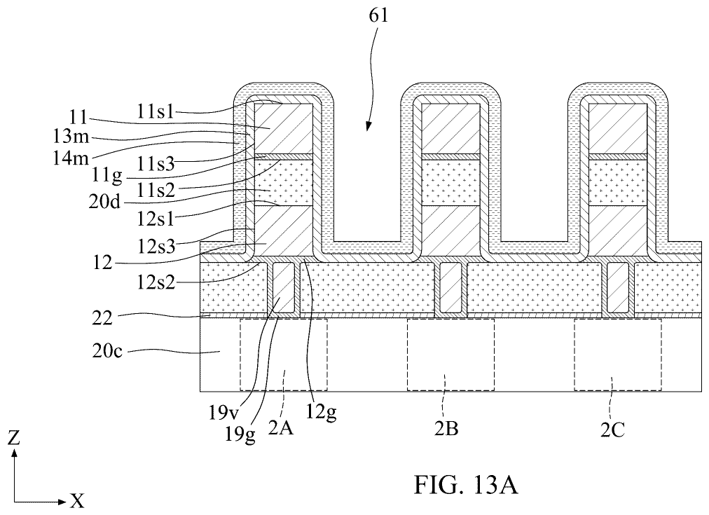

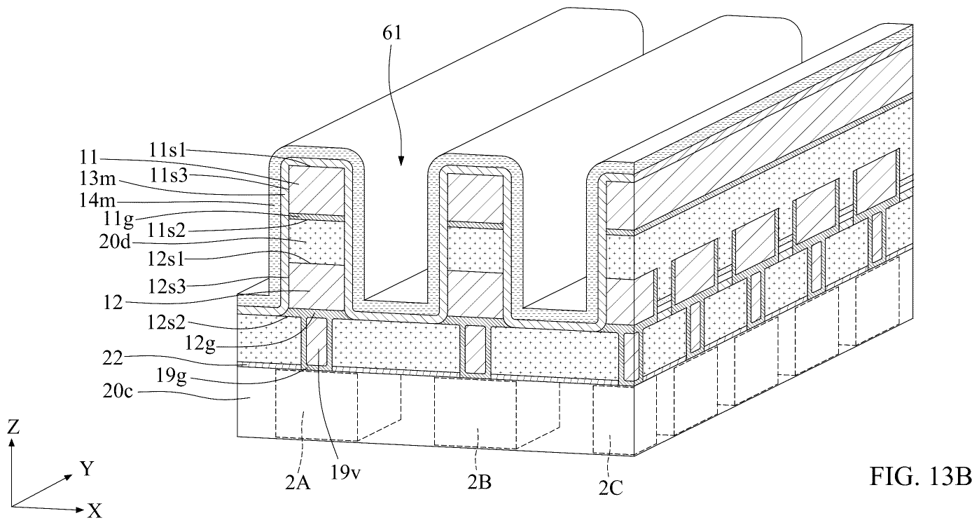

In FIGS. 13A and 13B, a gate dielectric layer material 14m is formed over the oxide semiconductor layer material 13m. The gate dielectric layer material 14m may be conformal to the oxide semiconductor layer material 13m.

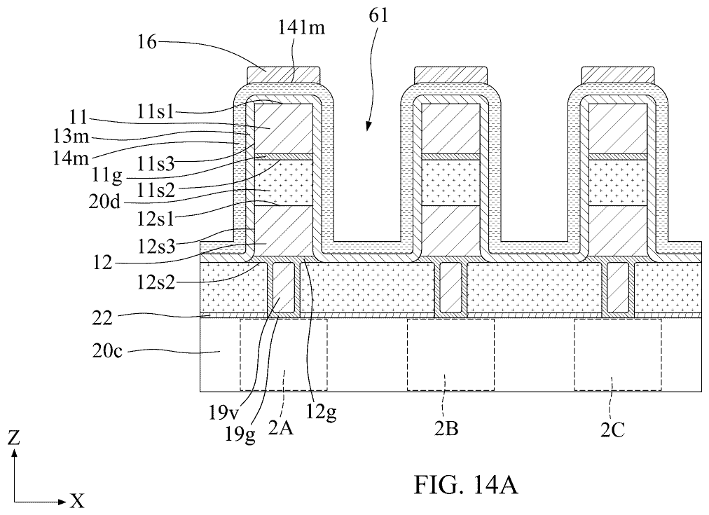

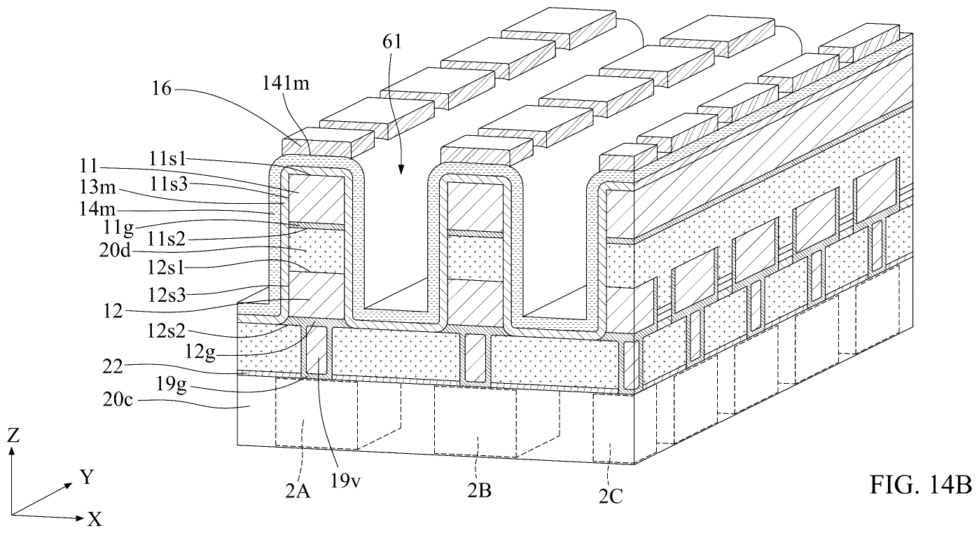

In FIGS. 14A and 14B, a barrier layer 16 may be formed over a top portion 141m of the gate dielectric layer material 14m. The barrier layer 16 may have a plurality of barrier layer regions over the top portion 141m of the gate dielectric layer material 14m. The barrier layer 16 may be formed by various processes. In some embodiments, a barrier layer material is formed over the gate dielectric layer material 14m and then etched with a patterned photoresist to define the barrier layer 16. In some embodiments, a photoresist is formed over the gate dielectric layer material 14m, and then a portion of the photoresist is removed to expose the top portion 141m of the gate dielectric layer material 14m. A barrier layer material is formed over the exposed top portion 141m and then the rest of the barrier layer material is removed along with the photoresist to form the barrier layer 16. In some embodiments, an insulating layer may be formed over the gate dielectric layer material 14m and then etched with a patterned photoresist to expose the top portion 141m of the gate dielectric layer material 14m. A barrier layer material is formed over the exposed top portion 141m, and then the rest of the barrier layer material is removed along with the insulating layer to form the barrier layer 16.

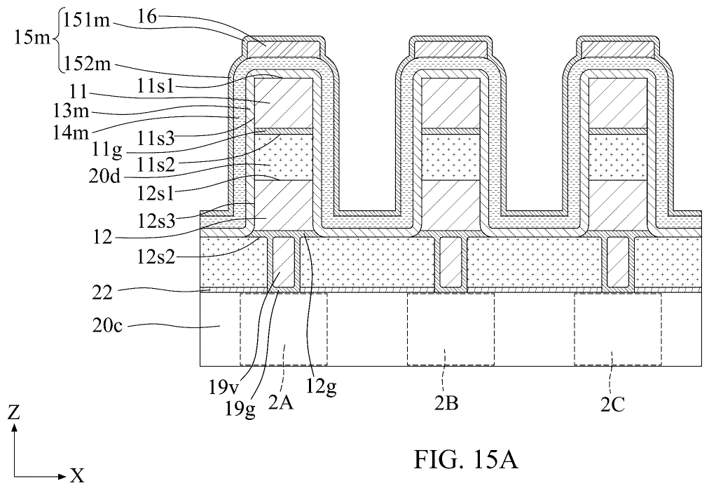

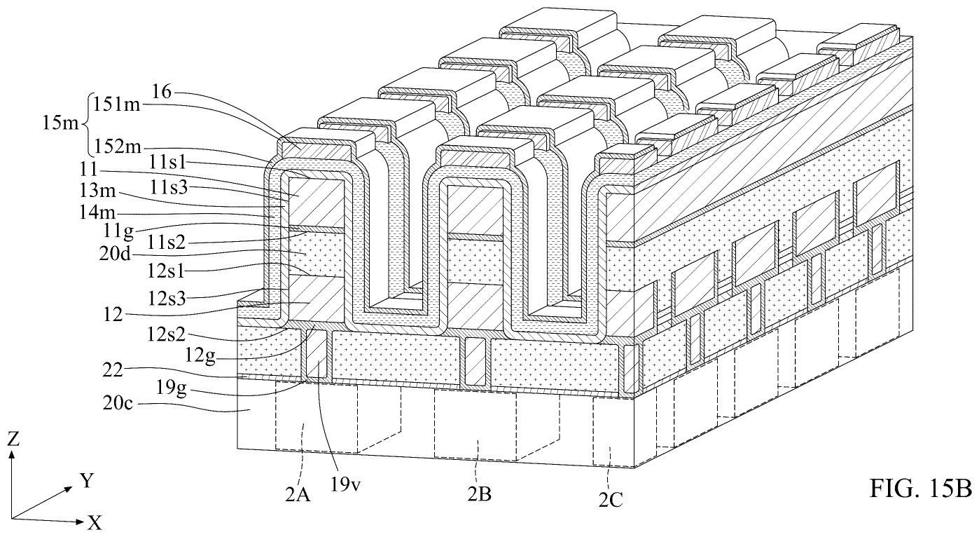

In FIGS. 15A and 15B, a gate electrode material 15m is formed over the barrier layer 16 and the gate dielectric layer material 14m. The gate electrode material 15m may have a plurality of regions. Each of regions extends in the X direction. The gate electrode material 15m may have a protrusion on the top thereof. The existence of the protrusion is a result of inserting the barrier layer 16 between the gate electrode material 15m and the gate dielectric layer material 14m. In some embodiments, the gate electrode material 15m may have a step structure. The gate electrode material 15m may include a first portion 151m and a second portion 152m. The first portion 151m is conformal to the barrier layer 16. The second portion 152 is conformal to the gate dielectric layer material 14m. The first portion 151m is separated from the gate dielectric layer material 14m, and the second portion 152m is in contact with the gate dielectric layer material 14m.

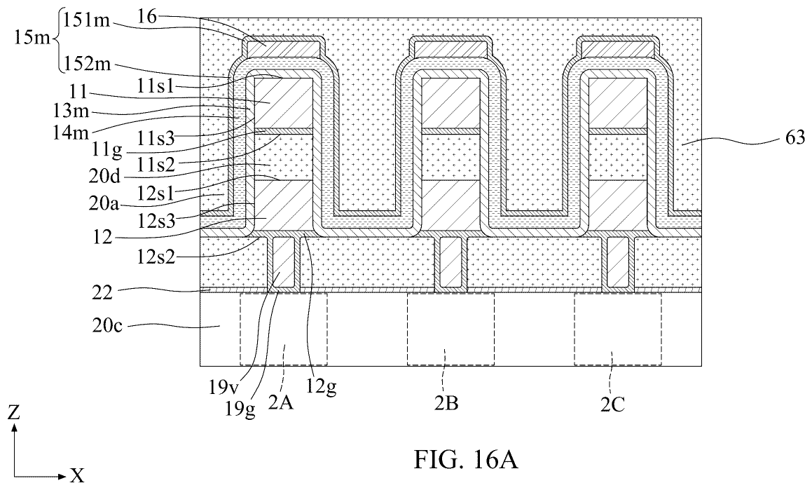

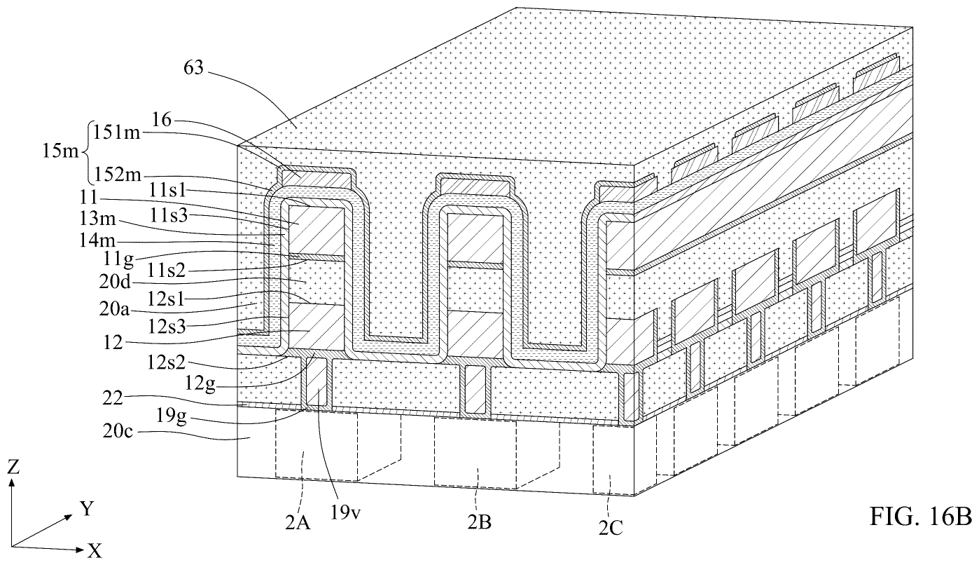

In FIGS. 16A and 16B, an insulating material 63 is filled into the holes 61 to cover the gate electrode material 15m.

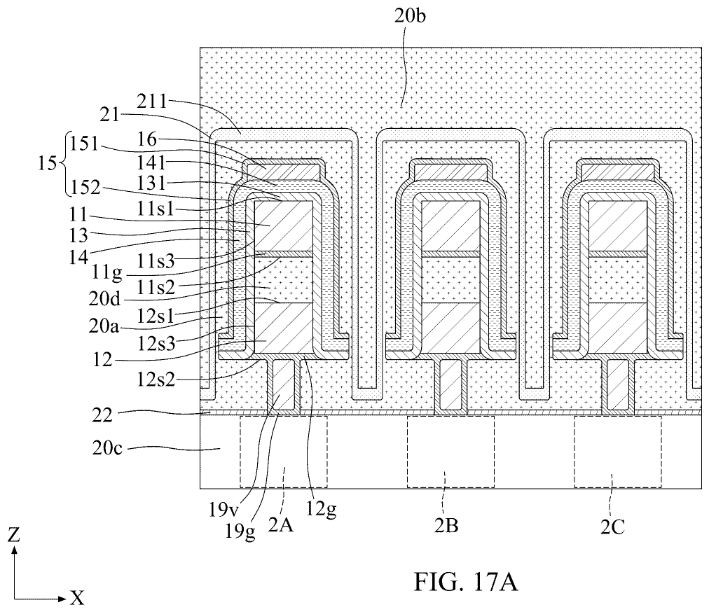

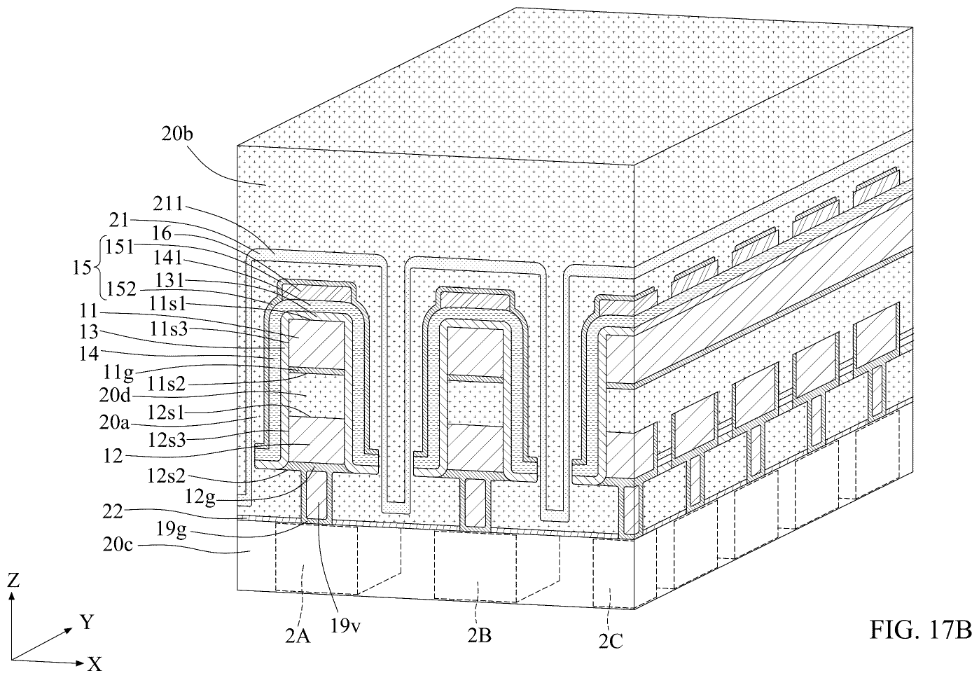

In FIGS. 17A and 17B, the oxide semiconductor layer material 13m, the gate dielectric layer material 14m, and the gate electrode material 15m are etched to define an oxide semiconductor layer 13, a gate dielectric layer 14, and a gate electrode 15 for each of transistors 1A, 1B, and 1C. The oxide semiconductor layer 13, the gate dielectric layer 14, and the gate electrode 15 may have an omega shape. The insulating material 63 is etched to define a plurality of trenches between the transistors 1A, 1B, and 1C.

Furthermore, an insulating layer material and a protection layer 21 are formed to surround the transistors 1A, 1B, and 1C. An insulating layer 20b is formed over the protection layer 21. The insulating material surrounded by the protection layer 21 is indicated as an insulating layer 20a.

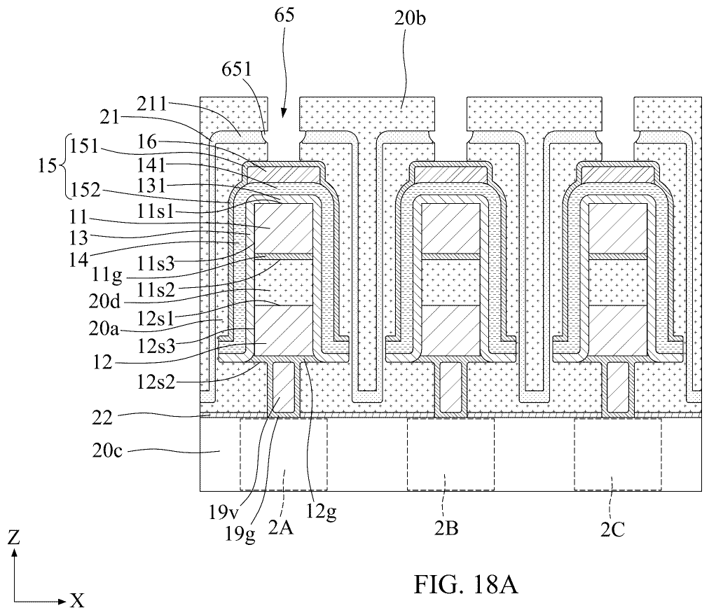

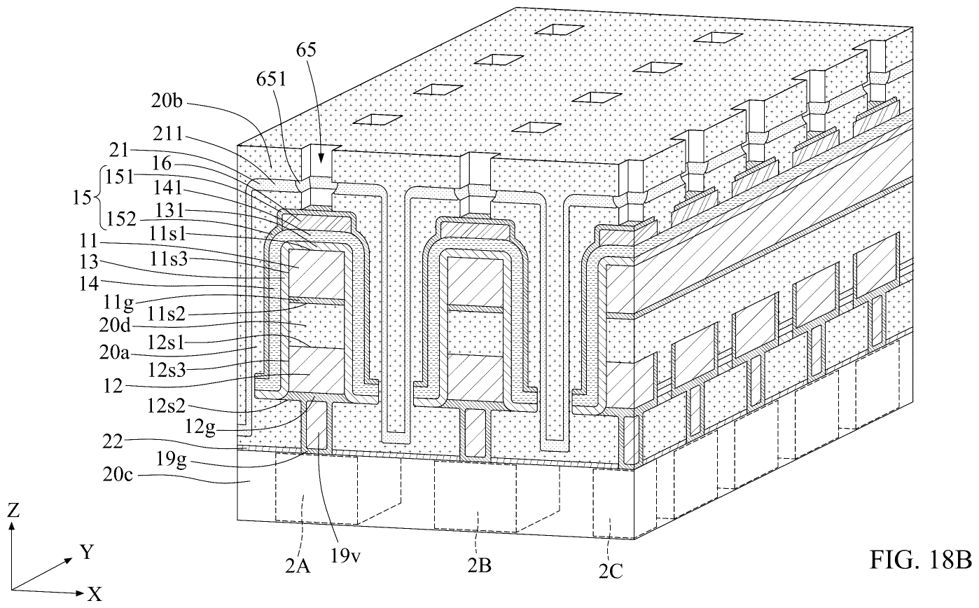

In FIGS. 18A and 18B, the insulating layers 20a and 20b and the protection layer 21 are etched to form a hole 65 over the first portion 151 of the gate electrode 15. During the etching process, the protection layer 21 may be laterally etched to a greater extent than the insulating layers 20a and 20b because of the etching selectivity. The hole 65 has a section 651 defined by the protection layer 21. The section 651 may have a diamond shape.

Afterwards, a conductive material may be formed in the hole 65 and over the insulating layer 20b to form a word line via 18v and a word line trace 18c, and then the semiconductor device 100 may be formed. The conductive via 18v is substantially aligned with the barrier layer 16. The drain electrode 11 is substantially aligned with the conductive via 18v and the barrier layer 16. The source electrode 12 is substantially aligned with the drain electrode 11, the conductive via 18v, and the barrier layer 16.

The word line via 18v and the word line trace 18c may be formed by a deposition process including chemical vapor deposition (CVD), physical vapor deposition (PVD), atomic layer deposition (ALD), other suitable methods, and/or combinations thereof.

The chamber (e.g., CVD chamber) used in the deposition process may have carrier gases, such as hydrogen. In some cases, the carrier gases (e.g., hydrogen) of the chamber may invade/diffuse/migrate/permeate into an exposed gate electrode and an inner gate dielectric layer and a channel region. The characteristics of the gate dielectric layer and the channel region can be adversely affected by the hydrogen impurity. In the present disclosure, the barrier layer 16 is formed between the hole 65 (corresponding to the location of the word line via 18v) and the gate dielectric layer 14/the oxide semiconductor layer 13. The barrier layer 16 may have a relatively low dielectric constant compared to the gate dielectric layer 14. The barrier layer 16 can reduce or stop the invasion/diffusion/migration/permeation of hydrogen into the gate dielectric layer 14 and the oxide semiconductor layer 13 during the deposition process of the word line via 18v and the word line trace 18c. With decreased or eliminated hydrogen diffusion into the oxide semiconductor layer 13, the threshold voltage can be improved.

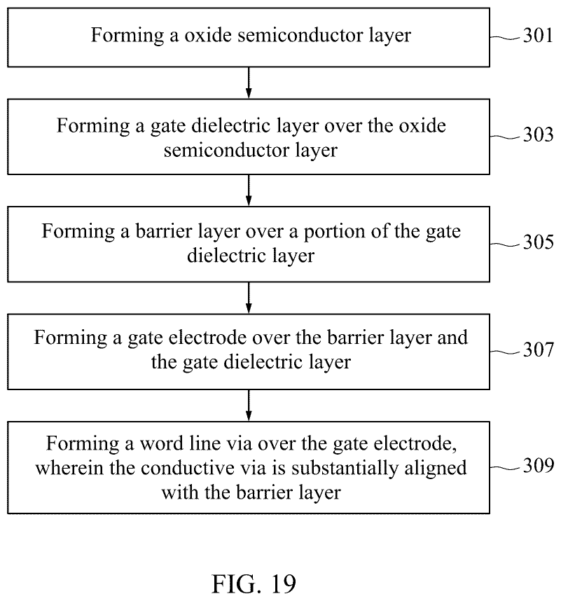

FIG. 19 is a flow diagram of a method 300 of manufacturing a semiconductor device (e.g., the semiconductor device 100) in accordance with some embodiments of the present disclosure. The method 300 includes a number of operations (301, 303, 305, 307, and 309) and the description and illustration are not deemed as limitations to the sequence of the operations and the structure of the semiconductor memory device.

In operation 301, an oxide semiconductor layer (e.g., the oxide semiconductor layer 13) is formed. The oxide semiconductor layer may be formed over a drain electrode (e.g., the drain electrode 11), an insulating layer (e.g., the insulating layer 20d), and a source electrode (e.g., the source electrode 12). In some embodiments, the operation 301 may include etching an oxide semiconductor layer (e.g., the oxide semiconductor layer 131m) to form the oxide semiconductor layer. The operation 301 may correspond to the structure shown in FIGS. 12A and 12B.

In operation 303, a gate dielectric layer (e.g., the gate dielectric layer 14) is formed over the oxide semiconductor layer. The gate dielectric layer is conformal to the oxide semiconductor layer. The operation 303 may correspond to the structure shown in FIGS. 13A and 13B. In some embodiments, the operation 303 may include etching a gate dielectric layer material (e.g., the gate dielectric layer material 14m) to form the gate dielectric layer.

In operation 305, a barrier layer (e.g., the barrier layer 16) is formed over a portion (e.g., the top portion 141) of the gate dielectric layer. In some embodiments, the barrier layer 16 is formed over the drain electrode. The barrier layer may be patterned to have a plurality of barrier layer regions over the top portion of the gate dielectric layer. The operation 305 may correspond to the structure shown in FIGS. 14A and 14B.

In operation 307, a gate electrode (e.g., the gate electrode 15) is formed over the barrier layer and the gate dielectric layer. The operation 307 may correspond to the structure shown in FIGS. 15A and 15B. In some embodiments, the operation 307 may include etching a gate electrode material (e.g., the gate electrode material 15m) to form the gate electrode.

In operation 309, a word line via (e.g., the word line via 18v) is formed over the gate electrode. The word line via is arranged to be substantially aligned with the barrier layer. The word line via may be formed in a hole (e.g., the hole 65) substantially aligned with the barrier layer and/or the drain electrode.

The word line via and the word line trace may be formed by a deposition process including chemical vapor deposition (CVD), physical vapor deposition (PVD), atomic layer deposition (ALD), other suitable methods, and/or combinations thereof.

The chamber (e.g., CVD chamber) used in the deposition process may have carrier gases, such as hydrogen. In some cases, the carrier gases (e.g., hydrogen) of the chamber may invade/diffuse/migrate/permeate into an exposed gate electrode and an inner gate dielectric layer and a channel region. The characteristics of the gate dielectric layer and the channel region can be adversely affected by the hydrogen impurity. In the present disclosure, the barrier layer is formed between the hole (corresponding to the location of the word line via) and the gate dielectric layer /he oxide semiconductor layer. The barrier layer may have a relatively low dielectric constant compared to the gate dielectric layer. The barrier layer can reduce or stop the invasion/diffusion/migration/permeation of hydrogen into the gate dielectric layer and the oxide semiconductor layer during the deposition process of the word line via and the word line trace. With decreased or eliminated hydrogen diffusion into the oxide semiconductor layer, the threshold voltage can be improved.

According to other embodiments, a semiconductor device is provided. The semiconductor device includes a gate dielectric layer, a gate electrode, and a barrier layer. The gate electrode surrounds the gate dielectric layer. The barrier layer is disposed between the gate dielectric layer and the gate electrode. The gate electrode is in contact with the barrier layer and the gate dielectric layer.

According to other embodiments, a semiconductor device is provided. The semiconductor device includes a drain electrode, a gate dielectric layer, and a gate electrode. The gate dielectric layer surrounds the drain electrode. The gate electrode surrounds the gate dielectric layer. The gate electrode has a step structure disposed over the drain electrode.

According to other embodiments, a method of manufacturing a semiconductor device is provided. The method includes: forming an oxide semiconductor layer; forming a gate dielectric layer over the oxide semiconductor layer; forming a barrier layer over a top portion of the gate dielectric layer; and forming a gate electrode over the barrier layer and the gate dielectric layer.

The methods and features of the present disclosure have been sufficiently described in the above examples and descriptions. It should be understood that any modifications or changes without departing from the spirit of the present disclosure are intended to be covered in the protection scope of the present disclosure.

Moreover, the scope of the present application in not intended to be limited to the particular embodiments of the process, machine, manufacture, and composition of matter, means, methods and steps described in the specification. As those skilled in the art will readily appreciate from the present disclosure, processes, machines, manufacture, composition of matter, means, methods or steps presently existing or later to be developed, that perform substantially the same function or achieve substantially the same result as the corresponding embodiments described herein, may be utilized according to the present disclosure.

Accordingly, the appended claims are intended to include within their scope: processes, machines, manufacture, and compositions of matter, means, methods or steps. In addition, each claim constitutes a separate embodiment, and the combination of various claims and embodiments are within the scope of the present disclosure.

What is claimed is:

1. A semiconductor device, comprising:
a gate dielectric layer;
a gate electrode surrounding the gate dielectric layer; and
a barrier layer disposed between the gate dielectric layer and the gate electrode,
wherein the gate electrode is in contact with the barrier layer and the gate dielectric layer.

2. The semiconductor device of claim 1, wherein the gate dielectric layer and the gate electrode meet at an edge of the barrier layer.

3. The semiconductor device of claim 1, wherein the gate electrode comprises a first portion conformally disposed on the barrier layer.

4. The semiconductor device of claim 1, further comprising a word line via connected to the gate electrode, wherein the word line via vertically overlaps the barrier layer.

5. The semiconductor device of claim 4, further comprising an oxide semiconductor layer, wherein the barrier layer is disposed between the oxide semiconductor layer and the word line via.

6. The semiconductor device of claim 5, wherein the oxide semiconductor layer and the gate dielectric layer each include a top portion below the barrier layer.

7. The semiconductor device of claim 4, wherein the word line via has a portion with a diamond shape.

8. The semiconductor device of claim 4, further comprising a transistor and a memory element connected to the transistor, wherein the transistor comprises the gate dielectric layer, the gate electrode, and the barrier layer.

9. The semiconductor device of claim 1, wherein a first dielectric constant of the barrier layer is smaller than a second dielectric constant of the gate dielectric layer.

10. A semiconductor device, comprising:
a drain electrode;
a gate dielectric layer surrounding the drain electrode; and
a gate electrode surrounding the gate dielectric layer,
wherein the gate electrode has a step structure disposed over the drain electrode.

11. The semiconductor device of claim 10, wherein the step structure comprises a first portion separated from the gate dielectric layer and a second portion in contact with the gate dielectric layer.

12. The semiconductor device of claim 11, wherein the drain electrode comprises a top surface and a lateral surface connected to the top surface, wherein the first portion vertically overlaps the top surface.

13. The semiconductor device of claim 12, further comprising a first oxide semiconductor layer disposed along the top surface and the lateral surface of the drain electrode.

14. The semiconductor device of claim 13, further comprising a second oxide semiconductor layer disposed between the first oxide semiconductor layer and the drain electrode, wherein a first doping concentration of the second oxide semiconductor layer is smaller than a second doping concentration of the first oxide semiconductor layer.

15. The semiconductor device of claim 14, wherein the second oxide semiconductor layer has a short side substantially coplanar with the top surface of the drain electrode.

16. The semiconductor device of claim 13, further comprising a liner disposed along the lateral surface of the drain electrode, wherein a first doping concentration of the liner is between a second doping concentration of the drain electrode and a third doping concentration of the first oxide semiconductor layer.

17. A method of manufacturing a semiconductor device, comprising:
forming an oxide semiconductor layer;
forming a gate dielectric layer over the oxide semiconductor layer;
forming a barrier layer over a top portion of the gate dielectric layer; and
forming a gate electrode over the barrier layer and the gate dielectric layer.

18. The method of claim 17, further comprising forming a word line via over the gate electrode, wherein the word line via is substantially aligned with the barrier layer.

19. The method of claim 18, further comprising forming a drain electrode surrounded by the oxide semiconductor layer, wherein the drain electrode is substantially aligned with the word line via and the barrier layer.

20. The method of claim 19, further comprising forming a source electrode below the drain electrode, wherein the source electrode is substantially aligned with the drain electrode, the word line via, and the barrier layer.
